(19) United States
(12) Patent Application Publication
(10) Pub. No.: US 2025/0393145 A1
(43) Pub. Date: Dec. 25, 2025

(54) ELECTRONIC DEVICE

(71) Applicant: Samsung Display Co., Ltd., Yongin-si (KR)

(72) Inventor: SUNGSANG AHN, Yongin-si (KR)

(21) Appl. No.: 19/246,977

(22) Filed: Jun. 24, 2025

(30) Foreign Application Priority Data
Jun. 25, 2024 (KR) 10-2024-0083093

(51) Int. Cl. H05K 5/02

(52) U.S. Cl. CPC H05K 5/0217

(57) ABSTRACT

An electronic device includes: a display module comprising a display area and a non-display area adjacent to the display area; a window module above the display module and comprising a first area overlapping the display module and a second area adjacent to the first area and defined along an edge of thereof; a bracket comprising a first portion facing a rear surface of the display module and a second portion extending from the first portion and facing a side surface of the window module; and a supporter under the window module, overlapping the second area, and having a thickness greater than a thickness of the display module.

### CROSS-REFERENCE TO RELATED APPLICATION

The present application claims priority to and the benefit of Korean Patent Application No. 10-2024-0083093, filed on Jun. 25, 2024, in the Korean Intellectual Property Office, the entire disclosure of which is incorporated herein by reference.

### BACKGROUND

### 1. Field

Aspects of some embodiments of the present disclosure relate to an electronic device including a display panel.

### 2. Description of Related Art

Various types of electronic devices, such as television sets, mobile phones, tablet computers, game units, or the like, are being developed. Recently, flexible electronic devices including a flexible display panel that is slidable or foldable are being developed.

Different from a rigid electronic device, the flexible electronic device is capable of being folded, rolled, or bent, without damaging the flexible electronic device. Because the shape of the flexible electronic device may be changed in various ways, it is easy to carry the flexible electronic device regardless of the size of its screen displaying images, and thus, a user convenience may be relatively improved.

Among the flexible electronic devices, the foldable electronic device may desirably maintain reliability and stability of components thereof when folded. However, a flexible electronic device may include multiple components that are stacked, and during the folding process, a slip phenomenon in which each component slides occurs.

The above information disclosed in this Background section is only for enhancement of understanding of the background and therefore the information discussed in this Background section does not necessarily constitute prior art.

### SUMMARY

Aspects of some embodiments of the present disclosure relate to an electronic device including a display panel. For example, aspects of some embodiments of the present disclosure relate to a foldable electronic device.

Aspects of some embodiments of the present disclosure include a foldable electronic device that relatively reduces the occurrence of a slip phenomenon and prevents the slip phenomenon from being viewed by a user without adding a separate component.

Aspects of some embodiments of the present disclosure include an electronic device including a display module including a display area and a non-display area adjacent to the display area, a window module above the display module and including a first area overlapping the display module and a second area adjacent to the first area and defined along an edge of the display module, a bracket including a first portion facing a rear surface of the display module and a second portion extending from the first portion and facing a side surface of the window module, and a supporter under the window module, overlapping the second area, and having a thickness greater than a thickness of the display module.

According to some embodiments, the display module further includes a display panel, and the display panel includes a folding area folded with respect to a folding axis extending in a first direction, a first non-folding area, and a second non-folding area spaced apart from the first non-folding area with the folding area interposed therebetween in a second direction intersecting the first direction.

According to some embodiments, the supporter includes first and second supporters in the first non-folding area and spaced apart from each other with the display module interposed therebetween and third and fourth supporters in the second non-folding area and spaced apart from each other with the display module interposed therebetween.

According to some embodiments, the first to fourth supporters extend in the second direction.

According to some embodiments, the supporter further includes a fifth supporter in the first non-folding area and extending in the first direction and a sixth supporter in the second non-folding area and extending in the first direction.

According to some embodiments, the supporter includes a first extension supporter extending in the second direction and at one side of the display module and a second extension supporter extending in the second direction and at the other side of the display module.

According to some embodiments, the first extension supporter includes a first folding portion overlapping the folding area and a first non-folding portion overlapping the first non-folding area or the second non-folding area.

According to some embodiments, the second extension supporter includes a second folding portion overlapping the folding area and a second non-folding portion overlapping the first non-folding area or the second non-folding area.

According to some embodiments, each of the first and second non-folding portions has a rigidity higher than a rigidity of each of the first and second folding portions.

According to some embodiments, the first and second non-folding portions include a polymer or a metal material.

According to some embodiments, the first and second folding portions include at least one of polyurethane, silicon, or rubber.

According to some embodiments, the supporter extends along an edge of the window module to surround the display module.

According to some embodiments, the supporter includes a folding portion overlapping the folding area and a non-folding portion overlapping the first and second non-folding areas, and the non-folding portion has a rigidity higher than a rigidity of the folding portion.

According to some embodiments, the supporter is between a side portion of the display module and the second portion.

According to some embodiments, the supporter is between a portion where the window module overlaps the second area and the first portion.

According to some embodiments, the supporter includes a polymer compound.

According to some embodiments, the supporter includes a metal material, and an adhesive material is coated on an upper surface and a lower surface of the supporter.

According to some embodiments, the window module includes a window above the display module, an adhesive layer on the window, and a protective layer on the adhesive layer.

According to some embodiments, the electronic device further includes a filling layer between the display module and the first portion.

According to some embodiments, the window module and the supporter are spaced apart from the second portion.

According to some embodiments, a portion in which the second area is defined in the window module has a width equal to or greater than 0.5 mm and equal to or smaller than 2 mm.

Aspects of some embodiments of the present disclosure include an electronic device including a display panel, a window module above the display panel and including a center portion overlapping the display panel and a peripheral portion protruded from the center portion toward an outside of the center portion, a bracket accommodating the display panel and the window module, and a supporter that is in contact with a lower surface of the peripheral portion.

According to some embodiments, the window module includes a folding area folded with respect to a folding axis extending in a first direction, a first non-folding area, and a second non-folding area spaced apart from the first non-folding area with the folding area interposed therebetween in a second direction intersecting the first direction.

According to some embodiments, the supporter includes a folding portion overlapping the folding area and including a first material and a non-folding portion overlapping the first and second non-folding areas and including a second material different from the first material.

According to some embodiments, the peripheral portion has a width equal to or greater than 0.5 mm and equal to or smaller than 2 mm.

According to some embodiments, the first material has a rigidity lower than a rigidity of the second material.

According to some embodiments, the folding portion includes a polymer or a metal material.

According to some embodiments, the non-folding portion includes at least one of polyurethane, silicon, or rubber.

According to the above, the electronic device may relatively reduce the occurrence of a slip phenomenon and prevent or reduce visibility of the slip phenomenon by a user without adding a separate member.

### BRIEF DESCRIPTION OF THE DRAWINGS

The above and other characteristics of embodiments according to the present disclosure will become readily apparent by reference to the following detailed description when considered in conjunction with the accompanying drawings wherein:

FIG. 1A is a perspective view of an electronic device according to some embodiments of the present disclosure;

FIG. 1B is a perspective view of an electronic device according to some embodiments of the present disclosure;

FIG. 1C is a plan view of an electronic device according to some embodiments of the present disclosure;

FIG. 1D is a perspective view of an electronic device according to some embodiments of the present disclosure;

FIG. 2A is a perspective view of an electronic device according to some embodiments of the present disclosure;

FIG. 2B is a perspective view of an electronic device according to some embodiments of the present disclosure;

FIG. 2C is a perspective view of an electronic device according to some embodiments of the present disclosure;

FIG. 3 is an exploded perspective view of the electronic device shown in FIG. 1A;

FIG. 4 is a cross-sectional view of an electronic device taken along a line I-I′ of FIG. 3;

FIG. 5 is a plan view of an electronic device according to some embodiments of the present disclosure;

FIG. 6 is a cross-sectional view of an electronic device taken along a line X-X′ of FIG. 5;

FIG. 7 is an enlarged view of an area AA′ of FIG. 6;

FIG. 8 is an enlarged view of an area BB′ of FIG. 6;

FIG. 9 is a cross-sectional view of an electronic device taken along a line X-X′ of FIG. 5;

FIG. 10 is a cross-sectional view of an electronic device taken along a line X-X′ of FIG. 5;

FIG. 11 is a cross-sectional view of an electronic device according to some embodiments of the present disclosure; and

FIGS. 12 to 15 are plan views of electronic devices according to some embodiments of the present disclosure.

### DETAILED DESCRIPTION

The present disclosure may be variously modified and realized in many different forms, and thus specific embodiments will be illustrated in the drawings and described in detail hereinbelow. However, the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of some embodiments of the present disclosure will be described in more detail with reference to accompanying drawings.

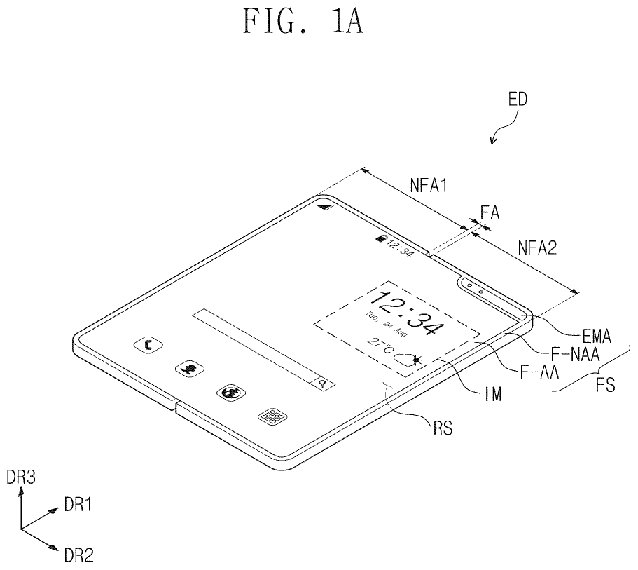

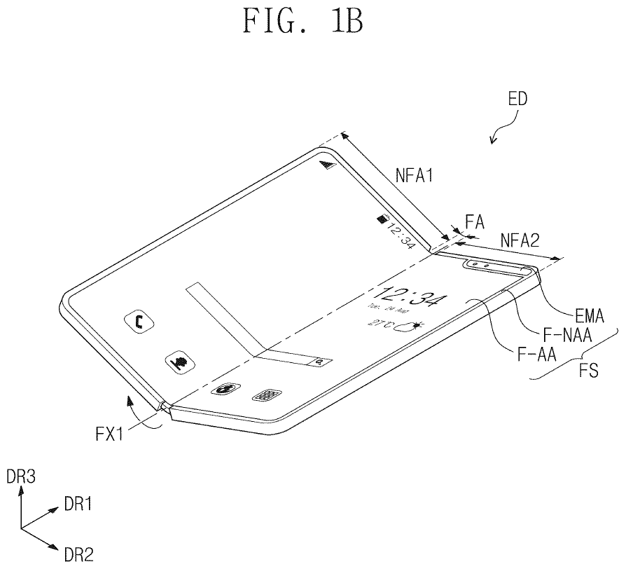

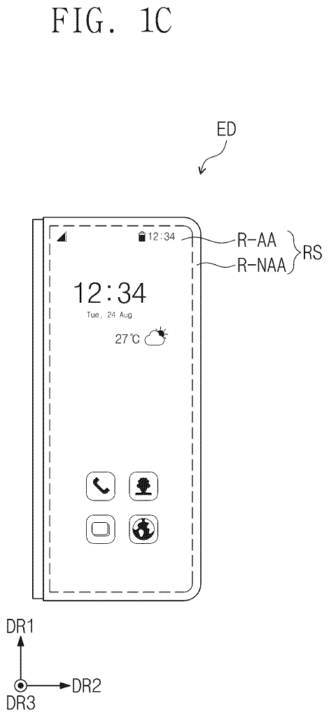

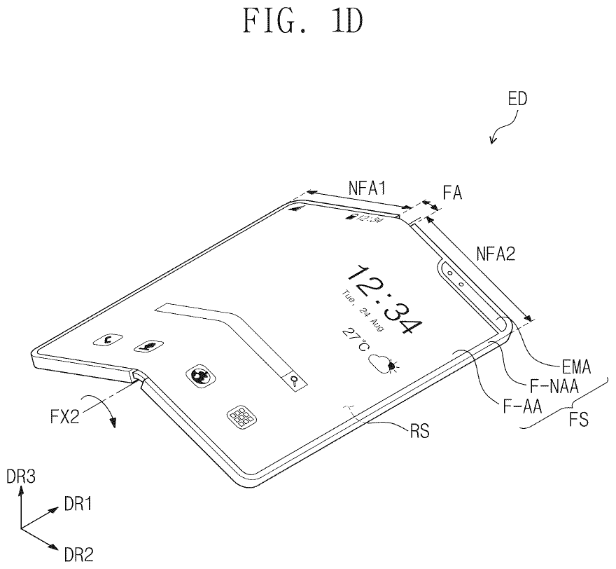

FIG. 1A is a perspective view of an electronic device ED according to some embodiments of the present disclosure. FIG. 1B is a perspective view of the electronic device ED according to some embodiments of the present disclosure. FIG. 1C is a plan view of the electronic device ED according to some embodiments of the present disclosure. FIG. 1D is a perspective view of the electronic device ED according to some embodiments of the present disclosure.

FIG. 1A is a perspective view of the electronic device ED in an unfolded state according to some embodiments of the present disclosure. The electronic device ED may be a device that is activated in response to electrical signals. As an example, the electronic device ED may be a mobile phone, a tablet computer, a car navigation unit, a game unit, or a wearable device, however, it should not be limited thereto or thereby. In FIGS. 1A to 1D, the mobile phone is shown as a representative example of the electronic device ED.

The electronic device ED may include a first display surface FS defined by a first direction DR1 and a second direction DR2 intersecting the first direction DR1. The electronic device ED may provide an image IM to a user through the first display surface FS. The electronic device ED may display the image IM through the first display surface FS, which is parallel (or substantially parallel) to each of the first direction DR1 and the second direction DR2, toward a third direction DR3.

In the present disclosure, the first direction DR1 may be perpendicular to the second direction DR2, and a third direction DR3 may be a normal line direction (e.g., a perpendicular direction) with respect to the plane defined by the first direction DR1 and the second direction DR2. A thickness direction of the electronic device ED may be parallel (or substantially parallel) to the third direction DR3. A front surface (or upper surface) and a rear surface (or lower surface) may be opposite to each other in the third direction DR3, and a normal line direction of each of the front surface (or upper surface) and the rear surface (or lower surface) may be parallel (or substantially parallel) to the third direction DR3. The front surface (or upper surface) may indicate a surface relatively closer to the first display surface FS, and the rear surface (or lower surface) may indicate a surface relatively far away from the first display surface FS. In addition, the rear surface (or lower surface) may indicate the surface restively closer to a second display surface RS described later. An upper side (or upper portion) may indicate a direction approaching the first display surface FS, and a lower side (or lower portion) may indicate a direction away from the first display surface FS.

A cross-section of each component may mean a plane parallel to the thickness direction DR3, and a plane of each component may mean a plane perpendicular to the thickness direction DR3. The plane may refer to the plane defined by the first direction DR1 and the second direction DR2. In the present disclosure, directions indicated by the first, second, and third directions DR1, DR2, and DR3 may be relative to each other and may be changed to other directions.

The electronic device ED may sense an external input applied thereto from an outside thereof. The external input may include various forms of inputs provided from the outside of the electronic device ED. For example, the external inputs may include a proximity input (e.g., hovering) applied when approaching close to or adjacent to the electronic device ED at a distance (e.g., a set or predetermined distance) as well as a touch input by a user's body (e.g., user's hand). In addition, the external inputs may be provided in the form of force, pressure, temperature, light, etc.

The electronic device ED may include the first display surface FS and the second display surface RS. The first display surface FS may include a first active area F-AA, a first peripheral area F-NAA, and an electronic module area EMA. The second display surface RS may be opposite to at least a portion of the first display surface FS. That is, the second display surface RS may be defined as a portion of a rear surface of the electronic device ED.

The first active area F-AA may be activated in response to the electrical signals. The electronic device ED may display the image IM through the first active area F-AA, and various external inputs may be sensed through the first active area F-AA.

The image IM may not be displayed through the first peripheral area F-NAA. The first peripheral area F-NAA may be defined adjacent to the first active area F-AA. The first peripheral area F-NAA may have a color (e.g., a set or predetermined color). The first peripheral area F-NAA may surround the first active area F-AA. Accordingly, the first active area F-AA may have a shape that is defined by the first peripheral area F-NAA, however, this is merely one example. The first peripheral area F-NAA may be defined adjacent to only one side of the first active area F-AA or may be omitted.

Various electronic modules may be located in the electronic module area EMA. For example, the electronic module may include at least one of a camera, a speaker, an optical sensor, or a thermal sensor. An external object may be sensed through the electronic module area EMA of the first display surface FS or the second display surface RS, or a sound signal, such as a voice, may be provided to the outside through the electronic module area EMA of the first display surface FS or the second display surface RS. In addition, the electronic module may include a plurality of components, however, it should not be limited to a particular embodiment.

The electronic module area EMA may be surrounded by the first peripheral area F-NAA, however, it should not be limited thereto or thereby. As an example, the electronic module area EMA may be surrounded by the first active area F-AA and the first peripheral area F-NAA, and the electronic module area EMA may be defined in the first active area F-AA.

The electronic device ED may include at least one folding area FA and a plurality of non-folding areas NFA1 and NFA2 extending from the folding area FA. As an example, a first non-folding area NFA1, the folding area FA, and a second non- folding area NFA2 may be sequentially defined along the second direction DR2. The second non-folding area NFA2 may be spaced apart from the first non-folding area NFA1 in the second direction DR2 with the folding area FA interposed therebetween. For example, the first non-folding area NFA1 may be located adjacent to one side of the folding area FA in the second direction DR2, and the second non-folding area NFA2 may be located adjacent to the other side of the folding area FA in the second direction DR2.

FIGS. 1A to 1D show the structure in which the electronic device ED includes one folding area FA as a representative example, however, the present disclosure should not be limited thereto or thereby, and the electronic device ED may include a plurality of folding areas defined therein. As an example, the electronic device may include two or more folding areas and three or more non-folding areas arranged with the folding area interposed therebetween.

FIG. 1B is a perspective view illustrating a folding operation of the electronic device ED according to some embodiments of the present disclosure. FIG. 1C is a perspective view illustrating the electronic device ED in a folded state according to some embodiments of the present disclosure. FIG. 1D is a perspective view illustrating a folding operation of the electronic device ED according to some embodiments of the present disclosure.

Referring to FIG. 1B, the electronic device ED may be folded with respect to a first folding axis FX1 extending in the first direction DR1. When the electronic device ED is folded, the folding area FA may have a curvature (e.g., a set or predetermined curvature) and a radius of curvature. The electronic device ED may be inwardly folded (in-folding) with respect to the first folding axis FX1 to allow the first non-folding area NFA1 to face the second non-folding area NFA2 and the first display surface FS not to be exposed to the outside.

Referring to FIG. 1C, the second display surface RS may be viewed by the user when the electronic device ED is inwardly folded. In this case, the second display surface RS may include a second active area R-AA through which images are displayed. The second active area R-AA may be activated in response to electrical signals. The images may be displayed through the second active area R-AA, and various external inputs may be sensed through the second active area R-AA.

In addition, the second display surface RS may include a second peripheral area R-NAA. The second peripheral area R-NAA may be defined adjacent to the second active area R-AA. The second peripheral area R-NAA may have a color (e.g., a set or predetermined color). The second peripheral area R-NAA may surround the second active area R-AA. According to some embodiments, the electronic device ED may further include an electronic module area in which an electronic module including various components is located in the second display surface RS.

According to some embodiments, when the electronic device ED is inwardly folded, a distance between the first non-folding area NFA1 and the second non-folding area NFA2 may be smaller than the radius of the circle defined by the radius of curvature of the folding area FA. In this case, the folding area FA may be folded to have a dumbbell shape, and the distance between the first non-folding area NFA1 and the second non-folding area NFA2 may be reduced. Accordingly, the electronic device ED may be slimmed down in the folded state.

Referring to FIG. 1D, the electronic device ED may be folded with respect to a second folding axis FX2 extending in the first direction DR1. The electronic device ED may be outwardly folded (out-folding) with respect to the second folding axis FX2 to allow the first display surface FS to be exposed to the outside. The display devices ED may be configured to repeat the unfolding operation and the in-folding operation or to repeat the unfolding operation and the out-folding operation, however, the present disclosure should not be limited thereto or thereby.

Meanwhile, FIGS. 1A to 1C show the electronic device ED folded with respect to one folding axis FX1 or FX2, however, the number of the folding axes and the number of non-folding areas should not be particularly limited. As an example, the electronic device ED may be folded with respect to multiple folding axes to allow a portion of the first display surface FS to face another portion of the first display surface FS and a portion of the second display surface RS to face another portion of the second display surface RS. In addition, the first and second folding axes FX1 and FX2 are shown as being parallel to long sides of the electronic device ED in the above embodiments, however, the present disclosure should not be limited thereto or thereby. According to some embodiments, the first and second folding axes FX1 and FX2 may be parallel (or substantially parallel) to short sides of the electronic device ED.

In the electronic device ED, the first non-folding area NFA1 and the second non-folding area NFA2 may be defined as areas respectively including the display surfaces FS and RS parallel to the plane defined by the first direction DR1 and the second direction DR2 in the folded state as shown in FIG. 1C, and the folding area FA may be defined as an area between the first non-folding area NFA1 and the second non-folding area NFA2. The folding area FA may include a curved portion that has a curvature (e.g., a set or predetermined curvature) in the folded state.

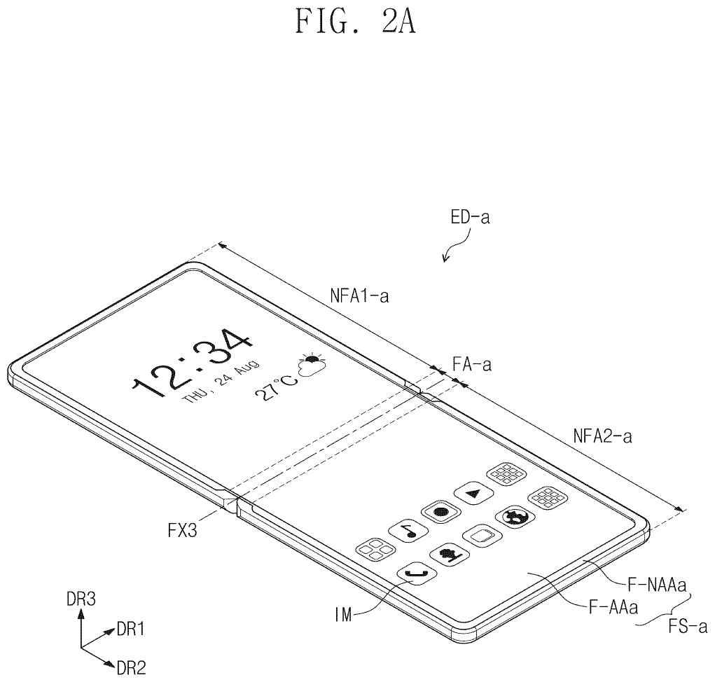

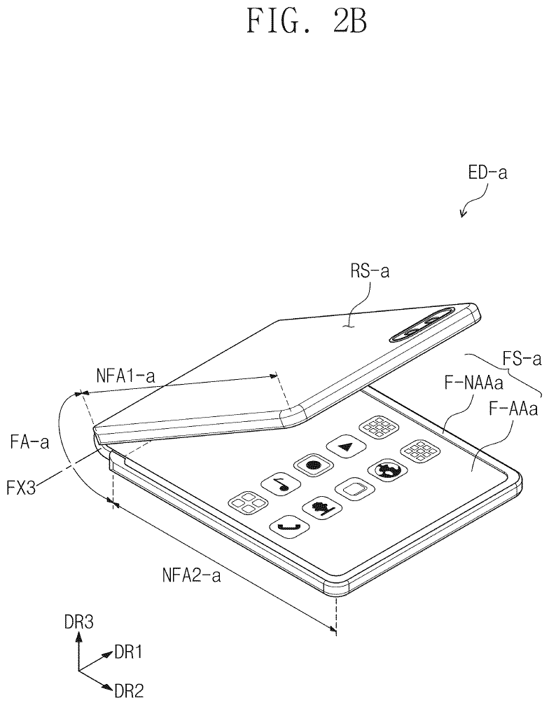

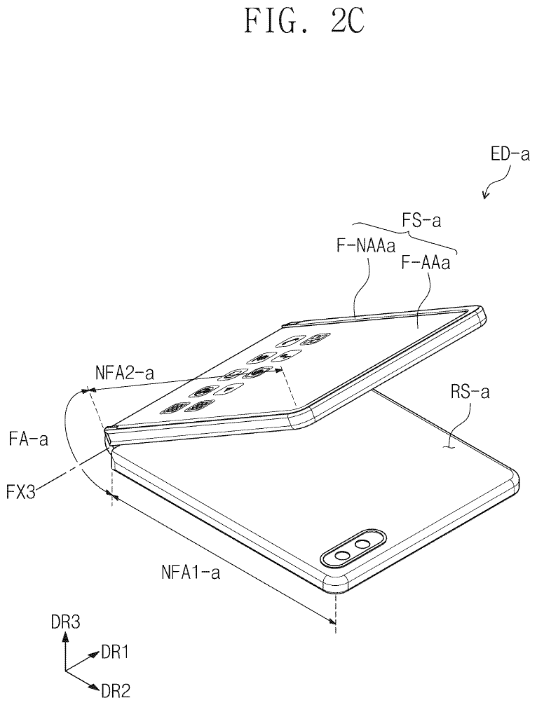

FIGS. 2A to 2C are perspective views of an electronic device ED-a according to some embodiments of the present disclosure.

FIG. 2A is a perspective view of the electronic device ED-a in an unfolding state. FIGS. 2B and 2C are perspective views illustrating a folding operation of the electronic device ED-a. FIG. 2B is a perspective view illustrating an in-folding operation of the electronic device ED-a. FIG. 2C is a perspective view illustrating an out-folding operation of the electronic device ED-a.

Referring to FIG. 2A, the electronic device ED-a may be folded with respect to a third folding axis FX3 extending in a direction parallel (or substantially parallel) to the first direction DR1. The direction in which the third folding axis FX3 extends may be parallel (or substantially parallel) to a direction in which a short side of the electronic device ED-a extends.

The electronic device ED-a may include a folding area FA-a, a first non-folding area NFA1-a adjacent to one side of the folding area FA-a, and a second non-folding area NFA2-a adjacent to the other side of the folding area FA-a. The first non-folding area NFA1-a may be spaced apart from the second non-folding area NFA2-a with the folding area FA-a interposed therebetween.

The folding area FA-a may be folded with respect to the third folding axis FX3. When the electronic device ED-a is folded, the folding area FA-a may have a curvature (e.g., a set or predetermined curvature) and a radius of curvature. The electronic device ED-a may be inwardly folded (in-folding) to allow the first non-folding area NFA1-a to face the second non-folding area NFA2-a and a display surface FS-a not to be exposed to the outside.

Referring to FIG. 2A, the display surface FS-a may be viewed by the user when the electronic device ED-a is in an unfolding state. As described with reference to FIGS. 1A to 1D, the display surface FS-a of the electronic device ED-a may include an active area F-AAa and a peripheral area F-NAAa. An image IM may be displayed through the active area F-AAa, and various external inputs may be sensed through the active area F-AAa.

Referring to FIG. 2B, a rear surface RS-a may be viewed by the user when the electronic device ED-a is inwardly folded. As an example, the rear surface RS-a may function as a second display surface through which images are displayed. In addition, the rear surface RS-a may include an electronic module area in which an electronic module including various components is located. An active area through which images are displayed may be further defined in the rear surface RS-a of the electronic device ED-a.

Referring to FIG. 2C, the electronic device ED-a may be folded with respect to the third folding axis FX3 to allow a portion of the rear surface RS-a, which overlaps the first non-folding area NFA1-a, to face another portion of the rear surface RS-a, which overlaps the second non-folding area NFA2-a.

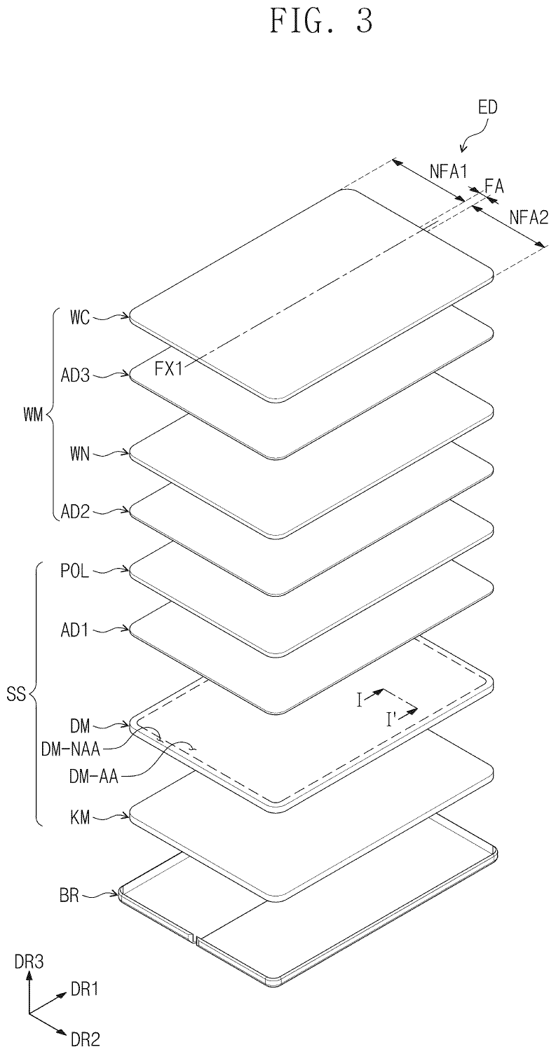

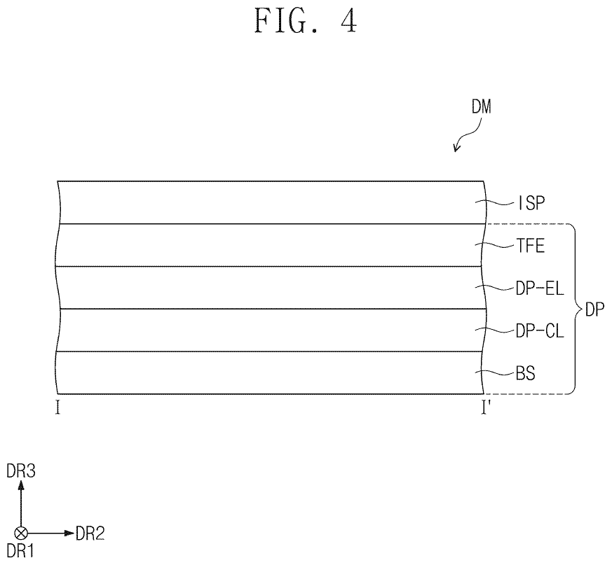

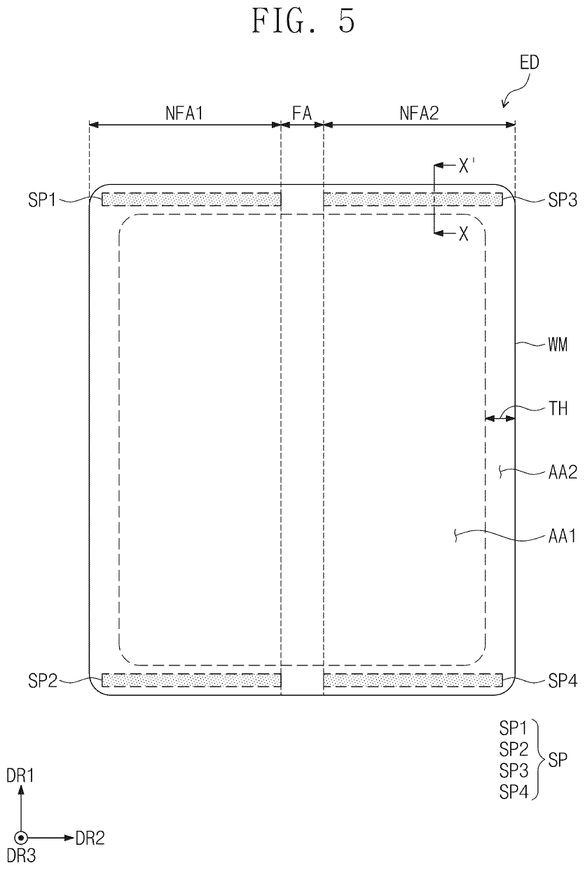

FIG. 3 is an exploded perspective view of the electronic device shown in FIG. 1A. FIG. 4 is a cross-sectional view of an electronic device taken along a line I-I′ of FIG. 3. FIG. 5 is a plan view of an electronic device according to some embodiments of the present disclosure.

Hereinafter, descriptions on the electronic device ED may be applied to the electronic device ED-a described with reference to FIGS. 2A to 2C.

Referring to FIG. 3, the electronic device ED may include a lower structure SS, a window module WM located on the lower structure SS, and a bracket BR.

The window module WM may include a second adhesive layer AD2, a window WN, a third adhesive layer AD3, and a protective layer WC. The lower structure SS may include a lower module KM, a display module DM, a first adhesive layer AD1, and an optical layer POL.

The bracket BR may be located under the lower module KM. The bracket BR may include a material with relatively high rigidity. As an example, the bracket BR may include a plurality of frames and/or plates formed of a glass, plastic, or metal material. The bracket BR may provide an accommodation space (e.g., a set or predetermined accommodation space). The display module DM may be accommodated in the accommodation space and may be protected from external impacts.

According to some embodiments, the lower module KM may include a plurality of components. As an example, the lower module KM may include at least one of a support plate, a lower film, or a shielding layer.

The display module DM may be activated in response to electrical signals. The activated display module DM may display the image IM (refer to FIG. 1A) through the first active area F-AA (refer to FIG. 1A) of the electronic device ED. The display module DM may include a display area DM-AA and a non-display area DM-NAA defined therein. The display area DM-AA may be activated in response to electrical signals. The non-display area DM-NAA may be defined adjacent to at least one side of the display area DM-AA. Circuits or lines to drive the display area DM-AA may be located in the non-display area DM-NAA.

The optical layer POL may be located between the display module DM and the window WN. The optical layer POL may be an anti-reflective layer to reduce a reflectance of the display module DM with respect to an external light incident to the display module DM from the outside. The optical layer POL may be formed on the display module DM through successive processes. The optical layer POL may include a polarizing plate or a color filter layer. As an example, the optical layer POL may include at least one of a retarder, a polarizer, a polarizing film, or a polarizing filter. According to some embodiments, the optical layer POL may include a plurality of color filters arranged in an arrangement (e.g., a set or predetermined arrangement) and a black matrix located adjacent to the color filters.

The image IM (refer to FIG. 1A) generated by the display module DM may be provided to the user after passing through the window WN. The window WN may include an optically transparent insulating material. The window WN may include a polymer substrate or a glass substrate. The window WN may include polyimide, polyacrylate, polymethylmethacrylate, polycarbonate, polyethylene naphthalate, polyvinylidene chloride, polyvinylidene difluoride, polystyrene, ethylene vinyl alcohol copolymer, or a combination thereof. However, this is merely an example, and a material for the window WN should not be limited thereto or thereby. As an example, the window WN may be a tempered glass substrate. The window WN may include an ultra-thin glass (UTG).

The protective layer WC may serve as a functional layer to protect one surface of the window WN. The protective layer WC may include a polymer film. The protective layer WC may include an anti-fingerprint coating agent, a hard coating agent, an anti-static agent, etc. The protective layer WC may be referred to as a cover window.

The electronic device ED may further include first, second, and third adhesive layers AD1, AD2, and AD3. The third adhesive layer AD3 may be located between the window WN and the protective layer WC. The second adhesive layer AD2 may be located between the optical layer POL and the window WN. The first adhesive layer AD1 may be located between the display module DM and the optical layer POL. Each of the first, second, and third adhesive layers AD1, AD2, and AD3 may include a conventional adhesive, such as a pressure sensitive adhesive (PSA), an optically clear adhesive (OCA), an optical clear resin (OCR), or the like, but it should not be particularly limited. According to some embodiments, at least one of the first, second, or third adhesive layers AD1, AD2, or AD3 may be omitted.

FIG. 4 is a cross-sectional view of the electronic device taken along a line I-I′ of FIG. 3. FIG. 4 is a cross-sectional view of the display module DM.

Referring to FIG. 4, the display module DM may include a display panel DP and an input sensing layer ISP located on the display panel DP.

The display panel DP may have a configuration that generates the image. The display panel DP may be a light-emitting type display panel. For example, the display panel DP may be an organic light emitting display panel, an inorganic light emitting display panel, a micro-LED display panel, a micro-OLED display panel, or a nano-LED display layer.

The display panel DP may include a base layer BS, a circuit element layer DP-CL, a display element layer DP-EL, and an encapsulation layer TFE, which are sequentially stacked. Different from the structure shown in FIG. 4, a functional layer may be further located between two layers adjacent to each other among the base layer BS, the circuit element layer DP-CL, the display element layer DP-EL, and the encapsulation layer TFE.

The base layer BS may provide a base surface on which the circuit element layer CP-CL is located. The base layer BS may be a flexible substrate that is bendable, foldable, or rollable. The base layer BS may be a glass substrate, a metal substrate, or a polymer substrate, however, it should not be limited thereto or thereby. According to some embodiments, the base layer BS may be an inorganic layer, an organic layer, or a composite material layer.

The base layer BS may have a single-layer or multi-layer structure. For instance, the base layer BS may include a first synthetic resin layer, an inorganic layer having a single-layer or multi-layer structure, and a second synthetic resin layer located on the inorganic layer. Each of the first and second synthetic resin layers may include a polyimide-based resin. In addition, each of the first and second synthetic resin layers may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin. Meanwhile, in the present disclosure, the term “X-based resin”, as used herein, refers to the resin that includes a functional group of X.

The circuit element layer DP-CL may be located on the base layer BS. The circuit element layer DP-CL may include an insulating layer, a semiconductor pattern, a conductive pattern, and a signal line. The display element layer DP-EL may be located on the circuit element layer DP-CL. The display element layer DP-EL may include a light emitting element. As an example, the light emitting element may include an organic light emitting material, an inorganic light emitting material, an organic-inorganic light emitting material, a quantum dot, a quantum rod, a micro-LED, or a nano-LED.

The encapsulation layer TFE may be located on the display element layer DP-EL. The encapsulation layer TFE may protect the display element layer DP-EL from moisture, oxygen, and a foreign substance such as dust particles. The encapsulation layer TFE may include at least one inorganic layer. As an example, the encapsulation layer TFE may include an inorganic layer, an organic layer, and an inorganic layer, which are sequentially stacked.

The input sensing layer ISP may be located on the display panel DP. The input sensing layer ISP may be located directly on the encapsulation layer TFE, however, the present disclosure should not be limited thereto or thereby. According to some embodiments, an adhesive member may be located between the input sensing layer ISP and the display panel DP.

In the present disclosure, the expression “one component is located directly on another component” means that no third component is located between the component and the other component. For example, when one component is “directly located” on another component, it means that the component and the other component are “contact” each other.

The input sensing layer ISP may sense an external input, may convert the sensed input to an input signal (e.g., a set or predetermined input signal), and may provide the input signal to the display panel DP. As an example, the input sensing layer ISP may be a touch sensing layer that senses a touch event. The input sensing layer ISP may sense a direct touch of the user, an indirect touch of the user, a direct touch of an object, or an indirect touch of an object.

The input sensing layer ISP may sense at least one of a position of a touch event applied from the outside and an intensity (pressure) of the touch event applied from the outside. The input sensing layer ISP may have various structures or may include various materials, but it should not be limited thereto or thereby. As an example, the input sensing layer ISP may sense the external input in a capacitive manner. The display panel DP may receive the input signal from the input sensing layer ISP and may generate the image corresponding to the input signal.

FIG. 5 is a plan view of the electronic device ED according to some embodiments of the present disclosure.

For the convenience of explanation, FIG. 5 illustrates a shape of the window module and a supporter in the plane, and other components are omitted. In FIG. 5, the supporter is illustrated as a dotted line. Hereinafter, the shape and position of the supporter will be described with reference to FIG. 5.

Referring to FIG. 5, the window module WM may include a first area AA1 and a second area AA2 adjacent to the first area AA1 and defined along an edge of the window module WM. The first area AA1 may overlap the display module DM (refer to FIG. 3) when viewed in the plane (or in a plan view). The second area AA2 may not overlap the display module DM.

In the present disclosure, a portion where the window module WM overlaps the first area AA1 may be referred to as a center portion, and a portion where the window module WM overlaps the second area AA2 may be referred to as a peripheral portion.

In the window module WM, the portion where the second area AA2 is defined may have a width TH equal to or greater than 0.5 millimeters (mm) (or about 0.5 mm) and equal to or smaller than 2 mm (or about 2 mm).

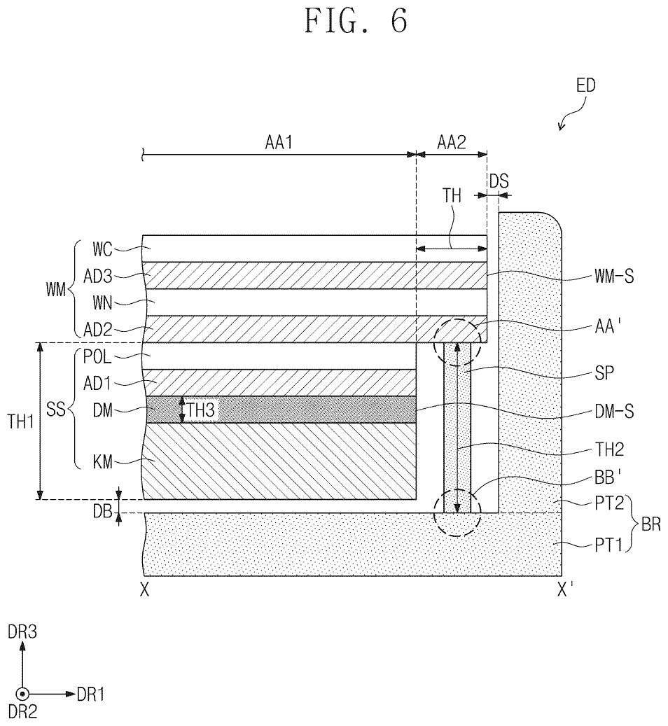

According to some embodiments, the supporter SP may overlap the peripheral portion of the window module WM. The supporter SP may be located under the window module WM. This will be described in detail with reference to FIG. 6.

The supporter SP may support the window module WM to prevent or reduce a slip phenomenon from occurring in the electronic device ED. In the present disclosure, the slip phenomenon may mean that at least some components, e.g., the display panel DP, the optical layer POL, or the like, among components of the electronic device ED are slipped when the electronic device ED is inwardly or outwardly folded. The supporter SP according to some embodiments may function to prevent or reduce the slip phenomenon from occurring or the slip phenomenon from being viewed, and this will be described in more detail with reference to FIGS. 6 to 9.

According to some embodiments, the supporter SP may include first, second, third, and fourth supporters SP1, SP2, SP3, and SP4.

The first and second supporters SP1 and SP2 may overlap the first non-folding area NFA1 and may be spaced apart from each other with the first area AA1 interposed therebetween.

The third and fourth supporters SP3 and SP4 may overlap the second non-folding area NFA2 and may be spaced apart from each other with the first area AA1 interposed therebetween.

The first and third supporters SP1 and SP3 may be spaced apart from each other with the folding area FA interposed therebetween. The second and fourth supporters SP2 and SP4 may be spaced apart from each other with the folding area FA interposed therebetween.

According to some embodiments, the first, second, third, and fourth supporters SP1, SP2, SP3, and SP4 may not be located in the folding area FA. Accordingly, the first, second, third, and fourth supporters SP1, SP2, SP3, and SP4 may not interfere with the folding operation of the electronic device ED, however, the present disclosure should not be limited thereto or thereby. As an example, a portion of the supporter SP may be located in the folding area FA, and this structure will be described in more detail later.

The first, second, third, and fourth supporters SP1, SP2, SP3, and SP4 may have the shape extending in the second direction DR2. As shown in FIG. 5, the first, second, third, and fourth supporters SP1, SP2, SP3, and SP4 may have the same (or substantially the same) rectangular shape extending in the second direction DR2 when viewed in the plane (or in a plan view), however, the present disclosure should not be limited thereto or thereby. According to some embodiments, the first, second, third, and fourth supporters SP1, SP2, SP3, and SP4 may have a shape other than the rectangular shape when viewed in the plane (or in a plan view) or may have different shapes from each other.

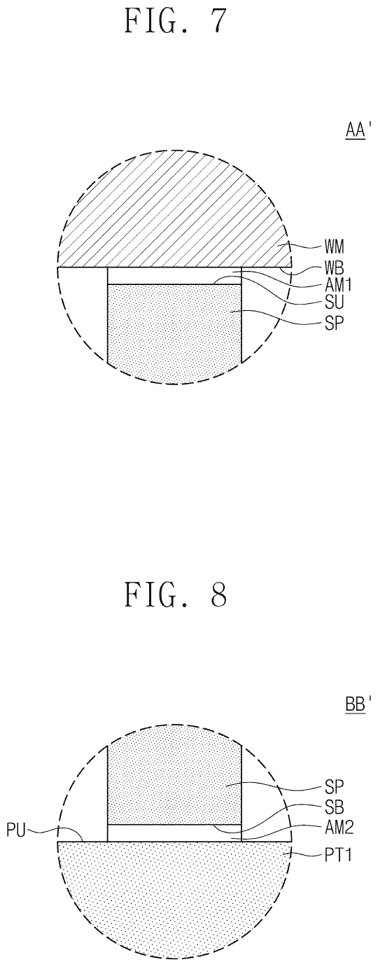

FIG. 6 is a cross-sectional view of the electronic device ED taken along a line X-X′ of FIG. 5. FIG. 7 is an enlarged view of an area AA′ of FIG. 6. FIG. 8 is an enlarged view of an area BB′ of FIG. 6.

Referring to FIG. 6, the electronic device ED may include the bracket BR, the lower structure SS, the window module WM located on the lower structure SS, and the supporter SP.

The bracket BR according to some embodiments may include a first portion PT1 facing a rear surface of the lower structure SS and a second portion PT2 extending from one side of the first portion PT1 to the third direction DR3 and facing a side surface WM-S of the window module to a side surface DM-S of the display module DM. However, in the present disclosure, the first portion PT1 and the second portion PT2 are separated for the convenience of explaining the bracket BR, and the bracket BR may be provided as a single integral unit.

The bracket BR may provide the accommodation space (e.g., the set or predetermined accommodation space). The bracket BR may accommodate the lower structure SS, the window module WM, and the supporter SP and may protect the lower structure SS, the window module WM, and the supporter SP from external impacts.

The lower structure SS may include the lower module KM, the display module DM, the first adhesive layer AD1, and the optical layer POL.

The lower structure SS may be spaced apart from the first portion PT1 in the third direction DR3. A distance between the lower structure SS and the first portion PT1 may be referred to as a separation distance DB.

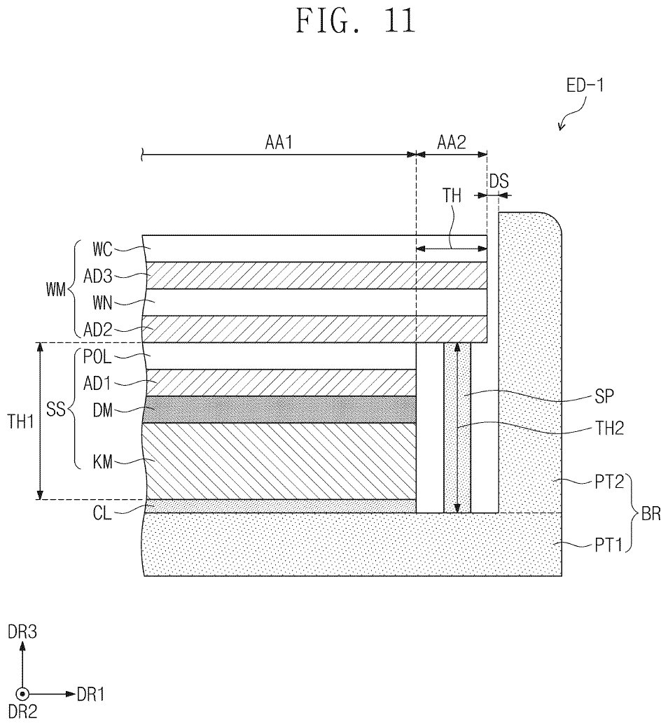

According to some embodiments, other components may not be located between the lower structure SS and the first portion PT1, however, the present disclosure should not be limited thereto or thereby. As an example, a filling layer may be further arranged to support the lower structure SS. This will be described in detail with reference to FIG. 11.

The lower structure SS may be spaced apart from the supporter SP in the first direction DR1 or the second direction DR2. Accordingly, even though the slip phenomenon occurs in the lower structure SS, the lower structure SS may not interfere with the supporter SP.

The window module WM may be spaced apart from the second portion PT2 in the first direction DR1 or the second direction DR2. The window module WM may be spaced apart from the second portion PT2 in the first direction DR1. A distance between the window module WM and the second portion PT2 may be referred to as a separation distance DS. When there is the separation distance DS between the window module WM and the bracket BR, a process of assembling the bracket BR and the window module WM may proceed smoothly in the process of manufacturing the electronic device ED.

The window module WM may be located on the display module DM. The window module WM may include the second adhesive layer AD2, the window WN located on the second adhesive layer AD2, the third adhesive layer AD3 located on the window WN, and the protective layer WC.

The supporter SP may be located between the peripheral portion of the window module WM and the first portion PT1. In detail, the supporter SP may be located between the peripheral portion of the window module WM and the first portion PT1. In addition, the supporter SP may be located between the lower structure SS and the second portion PT2 along the first direction DR1. The supporter SP may be spaced apart from the lower structure SS and the second portion PT2.

The supporter SP may have a thickness TH2 greater than a thickness TH1 of the lower structure SS. Accordingly, the supporter SP may be coupled with the first portion PT1 and may support the window module WM. In detail, one end of the supporter SP may be in contact with the window module WM, and the other end of the supporter SP may be in contact with the first portion PT1. The supporter SP may receive a vertical force from the first portion PT1 and may transfers the vertical force to the peripheral portion of the window module WM to support the window module WM. Accordingly, the lower structure SS attached to the window module WM may also be supported by the supporter SP.

In addition, because the lower structure SS includes the display module DM, the thickness TH2 of the supporter SP may be greater than a thickness TH3 of the display module DM.

The supporter SP may include one of a plastic material and a metal material. As an example, the supporter SP may include polymer compounds such as polyethylene terephthalate (PET), polycarbonate, polyamide, etc. According to some embodiments, the supporter SP may include the metal material such as magnesium, aluminum, etc.

FIG. 7 is an enlarged view of an area AA′ of FIG. 6. FIG. 8 is an enlarged view of an area BB′ of FIG. 6.

Referring to FIG. 7, a first adhesive material AM1 may be coated between the supporter SP and the window module WM. That is, the first adhesive material AM1 may be coated between an upper surface SU of the supporter SP and a lower surface WB of the window module WM.

As the first adhesive material AM1 is located between the supporter SP and the window module WM, the phenomenon in which the window module WM slips in the folding operation of the electronic device ED may be suppressed. That is, the window module WM may be attached to the upper surface SU of the supporter SP, and thus, the position of the window module WM may be fixed. Therefore, the slip phenomenon of the window module WM may be reduced or prevented.

Referring to FIG. 8, a second adhesive material AM2 may be coated between the supporter SP and the first portion PT1. That is, the second adhesive material AM2 may be coated between an upper surface PU of the first portion PT1 and a lower surface SB of the supporter SP. The first adhesive material AM1 and the second adhesive material AM2 may be the same (or substantially the same) as each other. Because the second adhesive material AM2 is located between the supporter SP and the first portion PT1, the supporter SP may be attached to the bracket BR (refer to FIG. 6).

Each of the first and second adhesive materials AM1 and AM2 and each of adhesive layers described later may include a conventional adhesive such as a pressure sensitive adhesive (PSA), an optically clear adhesive (OCA), an optical clear resin (OCR), etc., however, they should not be particularly limited.

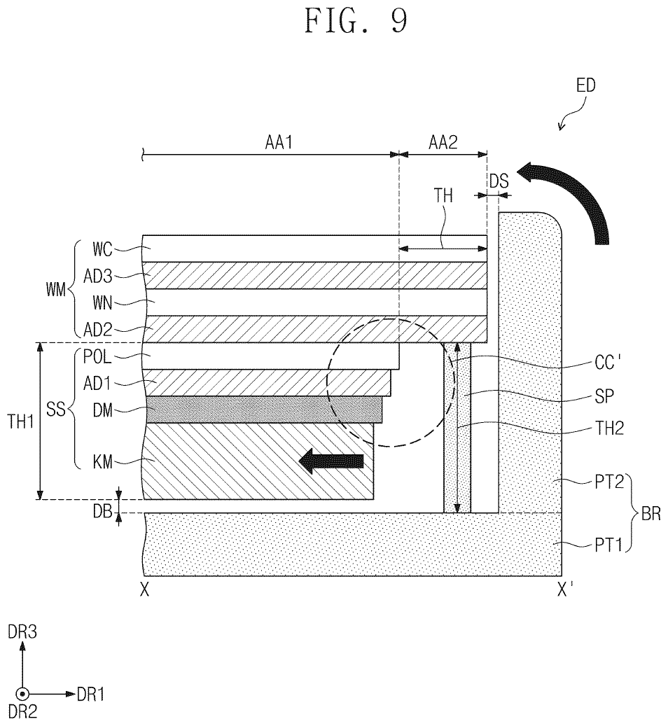

FIG. 9 is a cross-sectional view of the electronic device ED taken along a line X-X′ of FIG. 5. FIG. 9 is a cross-sectional view of a portion of the electronic device ED corresponding to the line X-X′ of FIG. 5 when the electronic device ED is inwardly folded.

In an area CC′ of FIG. 9, the slip phenomenon caused by differences in the amount of sliding according to the radius of curvature is shown as an example. That is, when the electronic device is inwardly folded, the lower the component among those housed within the accommodation space of the bracket, the longer the slippage distance toward the center of the bracket along the first direction. Due to this difference in slippage distance, the components may be arranged in a stepped formation.

However, because the window module WM is held by the supporter SP, occurrence of the slip phenomenon may be prevented or reduced. Accordingly, the separation distance DS between the window module WM and the second portion PT2 may be the same or substantially the same as before folding. In the present disclosure, the expression “substantially the same” includes cases where, when comparing before and after the folding, there is a difference that does not affect the user's visibility.

According to a conventional foldable electronic device, the supporter is located under the lower module KM, and the lower module KM and the first portion PT1 are fixed to each other by the supporter. In this case, the slip phenomenon of the components constituting the electronic device occurs at an outer side with respect to the supporter. In the present disclosure, an “inner” side of the supporter SP may refer to a position close to the center of the electronic device with respect to the supporter SP, and the “outer” side may refer to a direction toward the outer periphery of the electronic device with respect to the supporter SP.

That is, because the slip phenomenon occurs at the outer side with respect to the supporter in the conventional foldable electronic device, it is required to secure sufficient separation space in the second area AA2 to avoid the interference between the display module DM and the second portion PT2. In addition, it is required to place a separate decorative element to block the slip phenomenon from being viewed by the user.

However, according to the electronic device ED of the present disclosure, the position where the slip phenomenon occurs is changed due to the position of the supporter SP and the fixation of the window module WM by the supporter SP. That is, when the electronic device ED is inwardly folded, the slip phenomenon occurs at the inner side with respect to the supporter SP. In addition, the window module WM fixed by the supporter SP is located above with respect to the third direction DR3 based on the area where the slip phenomenon occurs, the slip phenomenon may be prevented from being viewed without employing the separate decorative element.

Accordingly, the size of the first peripheral area F-NAA (refer to FIG. 1A) may be reduced in the electronic device ED according to the present disclosure compared to the conventional electronic device. In addition, because there is no need to place the separate decorative element to prevent or reduce instances of the slip phenomenon being viewed by the user, the manufacturing process of the electronic device may be relatively simplified.

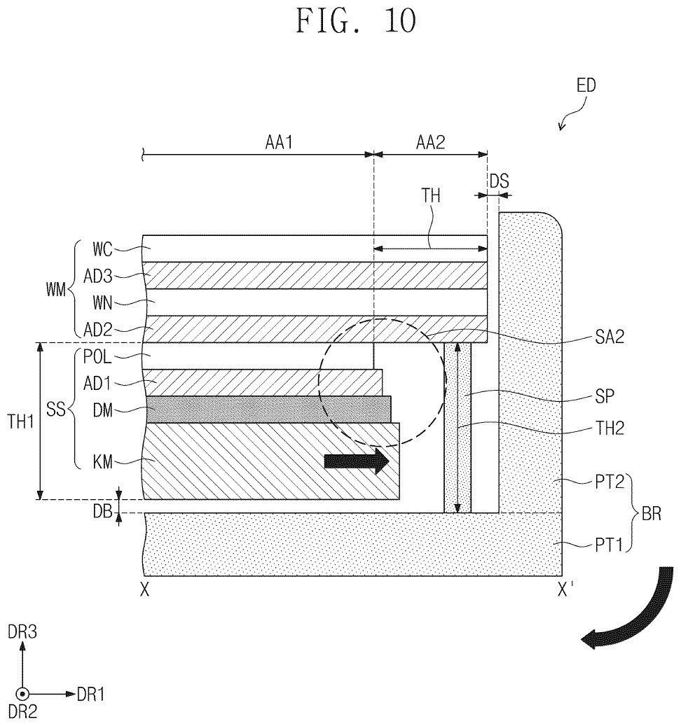

FIG. 10 is a cross-sectional view of the electronic device ED taken along a line X-X′ of FIG. 5. FIG. 10 is a cross-sectional view of a portion of the electronic device ED corresponding to the line X-X′ of FIG. 5 when the electronic device ED is outwardly folded.

Because the window module WM is fixed by the supporter SP, the occurrence of the slip phenomenon may be prevented or reduced. Therefore, the separation distance DS between the window module WM and the second portion PT2 may be the same or substantially the same as before folding.

Referring to FIG. 10, even though the electronic device ED is outwardly folded, the slip phenomenon occurs at the inner side with respect to the supporter SP, and thus, the display module DM or the lower module KM where the slip phenomenon occurs may be prevented from being viewed due to the window module WM.

Accordingly, even though the electronic device ED is outwardly folded, the same (or substantially the same) effect may occur as compared when the electronic device ED is inwardly folded.

FIG. 11 is a cross-sectional view of an electronic device ED-1 according to some embodiments of the present disclosure. The cross-section of the electronic device ED-1 shown in FIG. 11 may correspond to the cross-section of the electronic device ED described with reference to FIG. 6. In FIG. 11, the same/similar reference numerals denote the same/similar elements in FIGS. 1 to 10, and thus, some detailed descriptions of the same/similar elements may be omitted.

The electronic device ED-1 according to some embodiments may further include a filling layer CL compared to the electronic device ED described with reference to FIGS. 5 to 10.

The filling layer CL may be located between a first portion PT1 and a lower structure SS. The filling layer CL may support the lower structure SS and may be filled between the first portion PT1 and the lower structure SS. In addition, the filling layer CL may prevent or reduce instances of the lower structure SS being compressed and plastic-deformed due to external impact and force.

The filling layer CL may include an elastomer such as sponge, foam, or urethane resin. In addition, the filling layer CL may include at least one of an acrylic-based polymer, a urethane-based polymer, a silicone-based polymer, or an imide-based polymer.

The filling layer CL may include a pressure-sensitive adhesive (PSA). That is, the filling layer CL may include a material that develops adhesive properties when a pressure is applied thereto and may include materials such as polymers, resins, and additives. The pressure-sensitive adhesive (PSA) may have a relatively low modulus.

The filling layer CL may include a foam tape. As an example, the filling layer CL may include an adhesive tape formed of a foam material including polyurethane, polyethylene, polyacryl, silicone rubber, etc.

According to some embodiments, the electronic device according to some embodiments may further include an adhesive layer located between the filling layer CL and the lower structure SS.

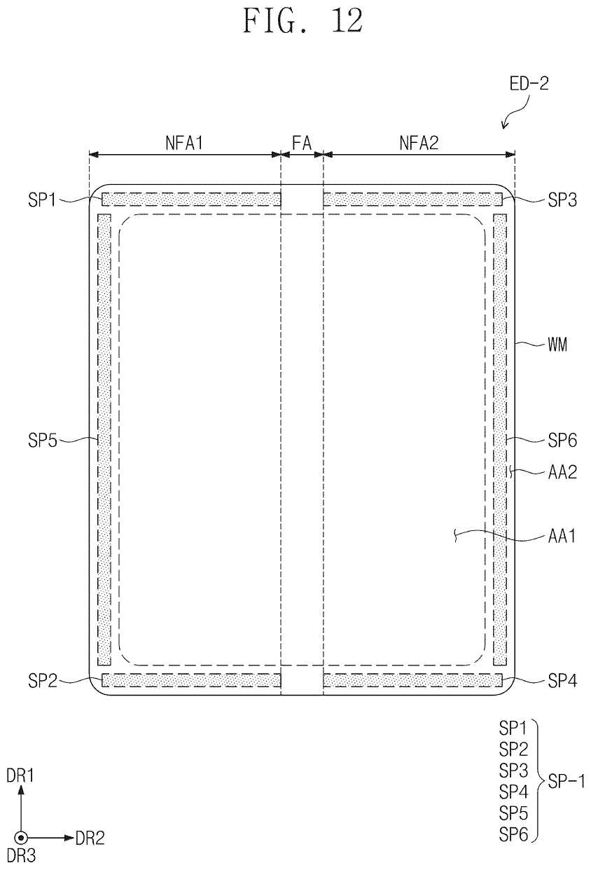

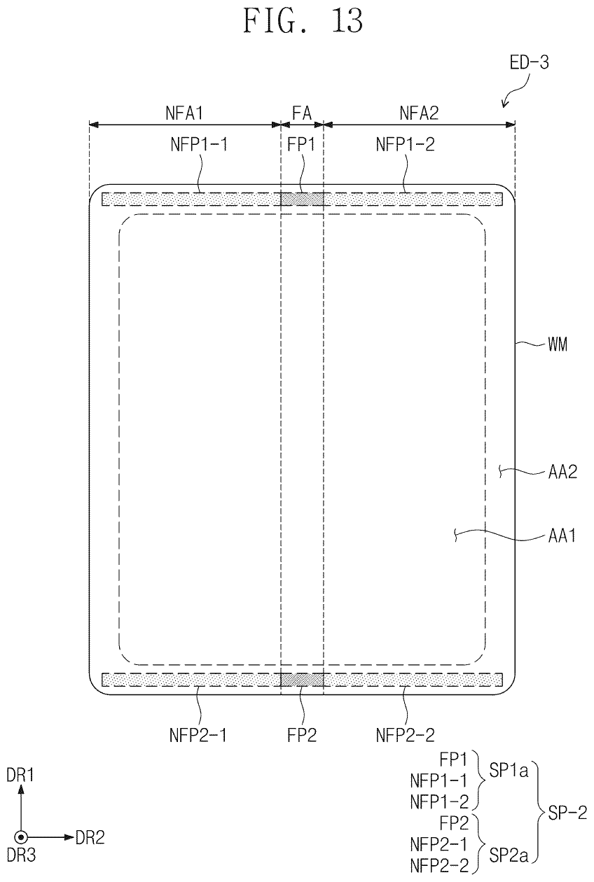

FIGS. 12 to 15 are plan views of electronic devices ED-2, ED-3, ED-4, and ED-5 according to some embodiments of the present disclosure.

FIGS. 12 to 15 are views illustrating an overlap relationship between a window module and a supporter. FIGS. 12 to 15 illustrates a shape of the window module and a shape of the supporter when viewed in the plane (or in a plan view), and other components are omitted. In FIGS. 12 to 15, the same/similar reference numerals denote the same/similar elements in FIGS. 1 to 10, and thus, some detailed descriptions of the same/similar elements may be omitted.

Referring to FIG. 12, the electronic device ED-2 may include a window module WM and a supporter SP-1.

According to some embodiments, the supporter SP-1 may include first, second, third, fourth, fifth, and sixth supporters SP1, SP2, SP3, SP4, SP5, and SP6. That is, the supporter SP-1 according to some embodiments may further include the fifth supporter SP5 and the sixth supporter SP6 compared to the supporter SP of the electronic device ED described with reference to FIG. 5.

The fifth supporter SP5 may be located in a first non-folding area NFA1 and may extend in the first direction DR1. The sixth supporter SP6 may be located in a second non-folding area NFA2 and may extend in the first direction DR1. The fifth supporter SP5 and the sixth supporter SP6 may be spaced apart from each other with a first area AA1 interposed therebetween.

One end of the fifth supporter SP5 may be adjacent to the first supporter SP1, and the other end of the fifth supporter SP5 may be adjacent to the second supporter SP2. The fifth supporter SP5 may be spaced apart from the first supporter SP1 and the second supporter SP2.

One end of the sixth supporter SP6 may be adjacent to third supporter SP3, and the other end of the sixth supporter SP6 may be adjacent to the fourth supporter SP4. The sixth supporter SP6 may be spaced apart from the third supporter SP3 and the fourth supporter SP4.

Descriptions of the cross-sectional shape, material, and function of the fifth and sixth supporters SP5 and SP6 may be the same as/similar to the descriptions of the supporter SP described with reference to FIG. 6, and some repetitive descriptions of the same elements may be omitted.

Referring to FIG. 13, the electronic device ED-3 may include a window module WM and a supporter SP-2.

According to some embodiments, the supporter SP-2 may include first and second extension supporters SP1a and SP2a extending in the second direction DR2.

The first and second extension supporters SP1a and SP2a may be located in a second area AA2. The first and second extension supporters SP1a and SP2a may be spaced apart from each other with a first area AA1 interposed therebetween.

The first extension supporter SP1a may include a first-first non-folding portion NFP1-1 overlapping the first non-folding area NFA1, a first folding portion FP1 overlapping the folding area FA, and a first-second non-folding portion NFP1-2 overlapping the second non-folding area NFA2.

The non-folding portion NFP1-1 may be spaced apart from the first-second non-folding portion NFP1-2 with the first folding portion FP1.

The extension supporter SP2a may include a second-first non-folding portion NFP2-1 overlapping the first non-folding area NFA1, a second folding portion FP2 overlapping the folding area FA, and a second-second non-folding portion NFP2-2 overlapping the second non-folding area NFA2.

The non-folding portion NFP2-1 may be spaced apart from the second-second non-folding portion NFP2-2 with the second folding portion FP2 interposed therebetween. The first-first non-folding portion NFP1-1 may be spaced apart from the first-second non-folding portion NFP1-2 with the first folding portion FP1.

The non-folding portion NFP1-1 and the second-first non-folding portion NFP2-1 may be spaced apart from each other with the first area AA1 interposed therebetween. The first-second non-folding portion NFP1-2 may be spaced apart from the second-second non-folding portion NFP2-2 with the first area AA1 interposed therebetween.

The first folding portion FP1 and the second folding portion FP2 may be spaced apart from each other with the first area AA1 interposed therebetween.

The first and second folding portions FP1 and FP2 may include a first material. The non-folding portions NFP1-1, NFP1-2, NFP2-1, and NFP2-2 may include a second material different from the first material. The first material may have a rigidity smaller than a rigidity of the second material. As an example, the first material may include at least one of polyurethane, silicon, or rubber, and the second material may include one of plastic or metal materials. However, the present disclosure should not be particularly limited as long as the rigidity of the first material is smaller than the rigidity of the second material.

According to the electronic device ED-3, the supporter SP-2 may include different materials depending on areas where the supporter SP-2 overlaps, and thus, the occurrence and recognition of the slip phenomenon may be effectively prevented or reduced, and the folding operation may be relatively smoothly performed. That is, because the non-folding portions NFP1-1, NFP1-2, NFP2-1, and NFP2-2 may include the material with relatively high rigidity, the components included in the electronic device ED-3 may be effectively prevented from being slipped. In addition, the folding portions FP1 and FP2 may include the material with relatively low rigidity, and thus, the folding operation of the electronic device ED-3 may provide flexibility to allow the folding operation to be smoothly performed in the folding area FA.

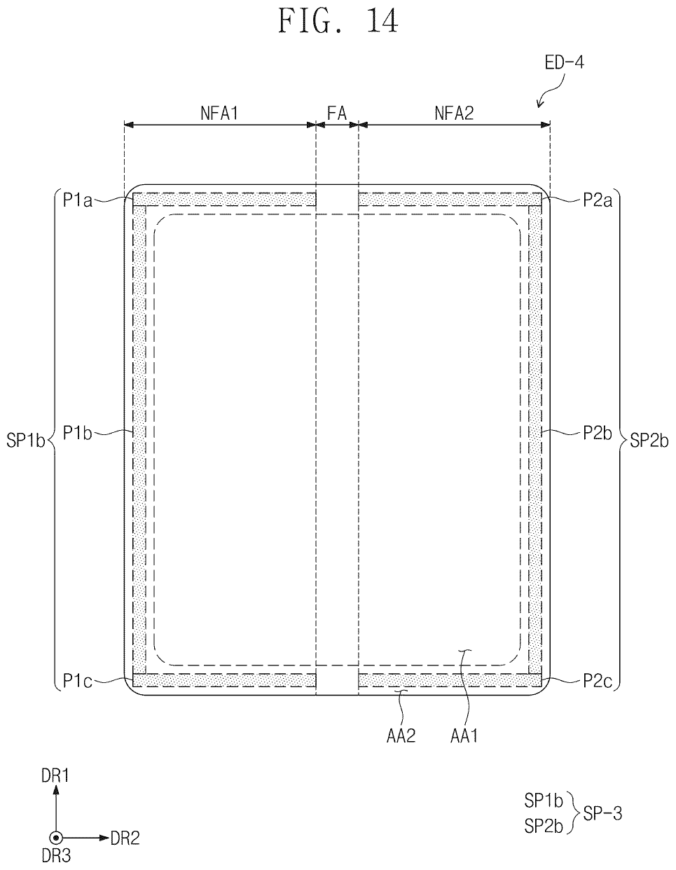

Referring to FIG. 14, the electronic device ED-4 may include a window module WM and a supporter SP-3.

The supporter SP-3 may include a first supporter SP1b and a second supporter SP2b.

The first supporter SP1b may include a first portion P1a, a second portion P1b, and a third portion P1c, and the second supporter SP2b may include a first portion P2a, a second portion P2b, and a third portion P2c.

The first portions P1a and P2a and the third portions P1c and P2c may extend in the second direction DR2. The second portions P1b and P2b may extend in the first direction DR1.

The first portions P1a and P2a may be spaced apart from each other with a folding area FA interposed therebetween. The third portions P1c and P2c may be spaced apart from each other with the folding area FA interposed therebetween. The second portions P1b and P2b may be spaced apart from each other with a first area AA1 interposed therebetween.

However, this is merely for convenience of explanation, and each of the first supporter SP1b and the second supporter SP2b may be provided as a single integral unit. That is, different from the electronic device ED-2 described with reference to FIG. 12, the electronic device ED-4 according to some embodiments of the present disclosure, portions of the supporter SP-3, which are located in a first non-folding area NFA1, may be provided as a single integral unit, and portions of the supporter SP-3, which are located in a second non-folding area NFA2, may be provided as a single integral unit.

Referring to FIG. 14, the first area AA1 may be surrounded by the first supporter SP1b in the first non-folding area NFA1, and the first area AA1 may be surrounded by the second supporter SP2b in the second non-folding area NFA2. Accordingly, the electronic device ED-4 according to some embodiments may prevent or reduce instances of contaminants such as moisture entering the display module DM (refer to FIG. 3) in the first area AA1.

According to some embodiments, the first and second supporters SP1b and SP2b may include a second material. The second material may be the same (or substantially the same) as the second material described with reference to FIG. 13, and thus, some repetitive details thereof may be omitted.

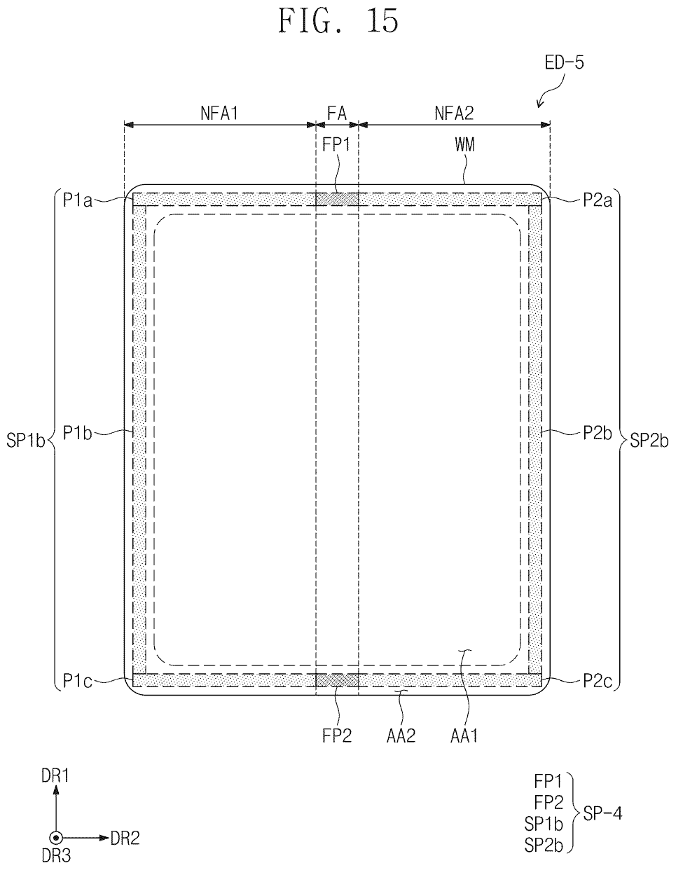

Referring to FIG. 15, the electronic device ED-5 may include a window module WM and a supporter SP-4.

The electronic device ED-5 shown in FIG. 15 may further include first and second folding portions FP1 and FP2 compared to the electronic device ED-4 shown in FIG. 14. Therefore, descriptions hereinafter will be focused on different features from those of the electronic device ED-4 shown in FIG. 14.

The first and second folding portions FP1 and FP2 may be located in a folding area FA. The first folding portion FP1 and the second folding portion FP2 may be spaced apart from each other with the first area AA1 interposed therebetween. The first folding portion FP1 may be located between first portions P1a and P2a. The second folding portion FP2 may be located between third portions P1c and P2c.

First and second supporters SP1b and SP2b and the first and second folding portions FP1 and FP2 are merely for convenience of explanation, and thus, they may be provided as a single integral unit.

Accordingly, the supporter SP-4 according to some embodiments may surround a display module (refer to DM of FIG. 3) located in the first area AA1. Therefore, the electronic device ED-5 according to some embodiments may prevent or reduce instances of contaminants such as moisture enter a display module (refer to DM of FIG. 3) located in the first area AA1.

Although aspects of some embodiments of the present disclosure have been described, it is understood that the present disclosure should not be limited to these embodiments but various changes and modifications can be made by one ordinary skilled in the art within the spirit and scope of embodiments according to the present disclosure as hereinafter claimed. Therefore, the disclosed subject matter should not be limited to any single embodiment described herein, and the scope of the present inventive concept shall be determined according to the appended claims, and their equivalents.

What is claimed is:

1. An electronic device comprising:
a display module comprising a display area and a non-display area adjacent to the display area;
a window module above the display module and comprising a first area overlapping the display module and a second area adjacent to the first area and defined along an edge of thereof;
a bracket comprising a first portion facing a rear surface of the display module and a second portion extending from the first portion and facing a side surface of the window module; and
a supporter under the window module, overlapping the second area, and having a thickness greater than a thickness of the display module.

2. The electronic device of claim 1, wherein the display module further comprises a display panel,
wherein the display panel comprises a folding area configured to be folded with respect to a folding axis extending in a first direction, a first non-folding area, and a second non-folding area spaced apart from the first non-folding area with the folding area interposed therebetween in a second direction intersecting the first direction.

3. The electronic device of claim 2, wherein the supporter comprises:
first and second supporters in the first non-folding area and spaced apart from each other with the display module interposed therebetween; and
third and fourth supporters in the second non-folding area and spaced apart from each other with the display module interposed therebetween, and the first to fourth supporters extend in the second direction.

4. The electronic device of claim 3, wherein the supporter further comprises:
a fifth supporter in the first non-folding area and extending in the first direction; and
a sixth supporter in the second non-folding area and extending in the first direction.

5. The electronic device of claim 2, wherein the supporter comprises:
a first extension supporter extending in the second direction and at one side of the display module; and
a second extension supporter extending in the second direction and at the other side of the display module, the first extension supporter comprises a first folding portion overlapping the folding area and a first non-folding portion overlapping the first non-folding area or the second non-folding area, and the second extension supporter comprises a second folding portion overlapping the folding area and a second non-folding portion overlapping the first non-folding area or the second non-folding area.

6. The electronic device of claim 5, wherein each of the first and second non-folding portions has a rigidity higher than a rigidity of each of the first and second folding portions.

7. The electronic device of claim 6, wherein the first and second non-folding portions each comprise a polymer or a metal material, and the first and second folding portions each comprise at least one of polyurethane, silicon, or rubber.

8. The electronic device of claim 5, wherein the supporter extends along an edge of the window module to surround the display module, the supporter comprises a folding portion overlapping the folding area and a non-folding portion overlapping the first and second non-folding areas, and the non-folding portion has a rigidity higher than a rigidity of the folding portion.

9. The electronic device of claim 1, wherein the supporter is between a side portion of the display module and the second portion.

10. The electronic device of claim 1, wherein the supporter is between a portion where the window module overlaps the second area and the first portion.

11. The electronic device of claim 1, wherein the supporter comprises a polymer compound.

12. The electronic device of claim 1, wherein the supporter comprises a metal material, and an adhesive material is coated on each of an upper surface and a lower surface of the supporter.

13. The electronic device of claim 1, wherein the window module comprises:
a window above the display module;
an adhesive layer on the window; and
a protective layer on the adhesive layer.

14. The electronic device of claim 1, further comprising a filling layer between the display module and the first portion.

15. The electronic device of claim 1, wherein the window module and the supporter are spaced apart from the second portion.

16. The electronic device of claim 1, wherein a portion in which the second area is defined in the window module has a width equal to or greater than 0.5 millimeters (mm) and equal to or smaller than 2 mm.

17. An electronic device comprising:
a display panel;
a window module above the display panel and comprising a center portion overlapping the display panel and a peripheral portion protruding from the center portion toward an outside of the center portion;
a bracket accommodating the display panel and the window module; and
a supporter that is in contact with a lower surface of the peripheral portion, wherein the window module comprises a folding area configured to be folded with respect to a folding axis extending in a first direction, a first non-folding area, and a second non-folding area spaced apart from the first non-folding area with the folding area interposed therebetween in a second direction intersecting the first direction, and the supporter comprises a folding portion overlapping the folding area and comprising a first material and a non-folding portion overlapping the first and second non-folding areas and comprising a second material different from the first material.

18. The electronic device of claim 17, wherein the peripheral portion has a width equal to or greater than 0.5 millimeters (mm) and equal to or smaller than 2 mm.

19. The electronic device of claim 17, wherein the first material has a rigidity lower than a rigidity of the second material.

20. The electronic device of claim 19, wherein the folding portion comprises a polymer or a metal material, and the non-folding portion comprises at least one of polyurethane, silicon, or rubber.
